(19) United States
(12) Patent Application Publication
(10) Pub. No.: US 2014/0224312 A1
(43) Pub. Date: Aug. 14, 2014

(54) DEPOSITION OF A HIGH SURFACE ENERGY THIN FILM LAYER FOR IMPROVED ADHESION OF GROUP I-III-VI2 SOLAR CELLS

(71) Applicants: Gregory Brown, Fremont, CA (US); Gregory Kimball, Campbell, CA (US); Peter Stone, Los Gatos, CA (US)

(72) Inventors: Gregory Brown, Fremont, CA (US); Gregory Kimball, Campbell, CA (US); Peter Stone, Los Gatos, CA (US)

(73) Assignee: NANOSOLAR, INC., San Jose, CA (US)

(21) Appl. No.: 13/766,712

(22) Filed: Feb. 13, 2013

(51) Int. Cl. H01L 31/0216

(52) U.S. Cl. CPC H01L 31/02167
USPC 136/256; 438/95

(57) ABSTRACT

A thin film photovoltaic cell includes a light absorption layer of Group I-III-VI₂ semiconductor materials and a high surface energy thin film layer that improves adhesion between the light absorption layer and an underlying electrode layer. The high surface energy thin film either replaces or is deposited on top of the back electrode to decrease the formation of voids at the back interface during absorber growth/deposition and thereby enabling a wider process window and improved cell efficiencies. It is emphasized that this abstract is provided to comply with the rules requiring an abstract that will allow a searcher or other reader to quickly ascertain the subject matter of the technical disclosure. It is submitted with the understanding that it will not be used to interpret or limit the scope or meaning of the claims.

### FIELD OF THE DISCLOSURE

This disclosure relates generally to photovoltaic or solar cells. More particularly, it relates to fabrication of a thin film solar cell having a compound semiconductor material as a light absorber.

### BACKGROUND OF THE INVENTION

Solar cells and solar modules convert sunlight into electricity. These electronic devices have been traditionally fabricated using silicon (Si) as a light-absorbing, semiconducting material in a relatively expensive production process. To make solar cells more economically viable, solar cell device architectures have been developed that can inexpensively make use of thin-film, preferably non-silicon, light-absorbing semiconductor materials with a chalcopyrite structure having excellent characteristics. Group I-III-VI₂ semiconductor materials are usually used as light absorber for thin film solar cells, such as but not limited to copper indium gallium selenide (CIGS). Specifically, CIGS is a I-III-VI₂ semiconductor material composed of copper, indium, gallium, and selenium. It is a tetrahedrally bonded semiconductor with chalcopyrite crystal structure.

In fabrication of thin film solar cells, the light absorber may be grown on a back electrode layer through a two-step process. The first step is deposition of the metal layers, followed by selenization with Se or H₂Se vapor or sulfidation with S or H₂S vapor. To produce higher efficient solar cells, a higher quality absorber layer is desirable.

It is within this context that aspects of the present disclosure arise.

### BRIEF DESCRIPTION OF THE DRAWINGS

FIG. 1 is a cross-sectional view showing an example of a solar cell of the present disclosure;

FIG. 2 shows a schematic of a roll-to-roll manufacturing system of a light absorption layer in accordance with the present disclosure; and

FIGS. 3A and 3B each show a flowchart of methods in accordance with aspects of the present disclosure.

FIG. 4A is a graph illustrating the effect of a high surface energy layer between an electrode layer and an absorber layer in accordance with aspects of the present disclosure.

FIG. 4B is a cross-sectional schematic diagram of a portion of a solar cell device illustrating the effect of a high surface energy layer between an electrode layer and an absorber layer in accordance with aspects of the present disclosure.

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the invention. Accordingly, the aspects of the present disclosure described below are set forth without any loss of generality to, and without imposing limitations upon, the claims that follow this description.

“Optional” or “optionally” means that the subsequently described circumstance may or may not occur, so that the description includes instances where the circumstance occurs and instances where it does not. For example, if a device optionally contains a feature for an anti-reflective film, this means that the anti-reflective film feature may or may not be present, and thus, the description includes both structures wherein a device possesses the anti-reflective film feature and structures wherein the anti-reflective film feature is not present.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a thickness range of about 1 nm to about 200 nm should be interpreted to include not only the explicitly recited limits of about 1 nm and about 200 nm, but also to include individual sizes such as but not limited to 2 nm, 3 nm, 4 nm, and sub-ranges such as 10 nm to 50 nm, 20 nm to 100 nm, etc. . . .

In forming a high quality absorber for a solar cell, a higher concentration of Se vapor or lower substrate temperature at the time of Se vapor introduction may be used. However, it has been determined that the higher concentration of Se vapor or lower substrate temperature at the time of Se vapor introduction can lead to voids at a back contact interface between the absorber layer and the underlying back electrode during the rapid thermal processing (RTP) and thus resulting in subsequent delamination. Improvements on adhesion between the light absorber layer and the back electrode are therefore desired.

This disclosure describes the deposition of a high surface energy thin film layer for replacement or on top of the back electrode to decrease interfacial void formation. The high surface energy layer may decrease the formation of voids at the back interface during absorber growth/deposition and thereby enabling a wider process window and improved cell efficiencies.

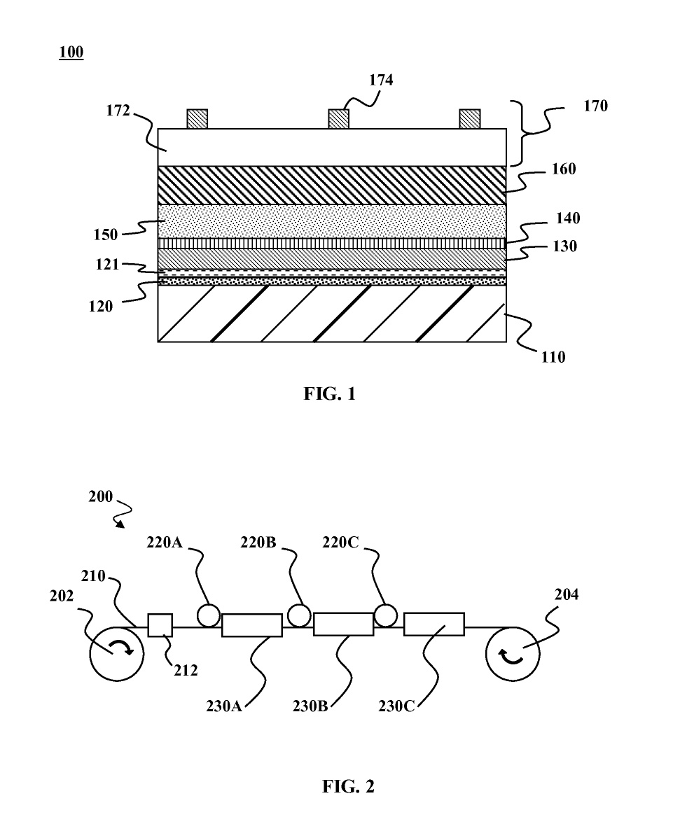

FIG. 1 shows a photovoltaic device in accordance with the present disclosure. A photovoltaic device 100 includes a substrate 110, an optional adhesion layer 120, a diffusion barrier layer 121, a back electrode layer 130, a high surface energy layer 140, a light-absorption layer 150, a buffer layer 160 and a transparent electrode layer 170.

The substrate 110 may be made of metal such as stainless steel or aluminum. Metals such as, but not limited to, copper, steel, coated aluminum, molybdenum, titanium, tin, metallized plastic films, or combinations of the foregoing may also be used as the substrate 110. When a conductive substrate is used, an insulating layer may be formed on the surface of the substrate to keep the surface insulated. Alternative substrates include but are not limited to ceramics, glasses, a polymer such as polyimides (PI), polyamides, polyetheretherketone (PEEK), Polyethersulfone (PES), polyetherimide (PEI), polyethylene naphtalate (PEN), Polyester (PET), related polymers, a metallized plastic, and/or combination of the above and/or similar materials. By way of non-limiting example, related polymers include those with similar structural and/or functional properties and/or material attributes. Any of these substrates may be in the form of foils, sheets, rolls, the like, or combinations thereof. Depending on the conditions of the surface, and material of the substrate, it may be useful to clean and/or smooth the substrate surface.

An optional adhesion layer 120 and diffusion barrier layer 121 may be incorporated between the electrode 130 and the substrate 110. The material of the adhesion layer 120 is selected to promote adhesion of the diffusion barrier layer 121 to the substrate 110 thereby improving adhesion of the electrode 130 to the substrate 110. By way of example, and not by way of limitation, the material of the adhesion layer 120 may be titanium (Ti). The diffusion barrier layer 121 may include a material selected to prevent diffusion of material between the substrate 110 and the electrode 130. The diffusion barrier layer 121 may be a conductive layer or it may be an electrically nonconductive layer. As non-limiting examples, the layer 121 may be composed of any of a variety of materials, including but not limited to chromium, vanadium, tungsten, and glass, or compounds such as nitrides (including tantalum nitride, tungsten nitride, titanium nitride, silicon nitride, zirconium nitride, and/or hafnium nitride), oxides, carbides, and/or any single or multiple combination of the foregoing. Although not limited to the following, the thickness of this layer can range from 10 nm to 200 nm, more preferably between 50 nm and 200 nm. In some embodiments, the layer may be from 10 nm to 30 nm. Optionally, an interfacial layer may be located above the electrode 130 and be comprised of a material such as including but not limited to chromium, vanadium, tungsten, and glass, or compounds such as nitrides (including tantalum nitride, tungsten nitride, titanium nitride, silicon nitride, zirconium nitride, and/or hafnium nitride), oxides, carbides, and/or any single or multiple combination of the foregoing.

The back electrode layer 130 may be a metal or semiconductor as long as it is electrically conductive. The thickness of this layer 130 may be in a range of about 0.1 micron to about 25 microns. In one example, molybdenum (Mo) has been widely used as a back electrode layer. The back electrode layer 130 may be deposited on the substrate 110 by DC sputtering or other methods. In order to enhance interfacial bonding with the light absorption layer 150, a high surface energy layer 140 is deposited on the back electrode layer 120.

A high surface energy layer 140 may be deposited or otherwise formed on top of the back electrode layer 130. By way of nonlimiting examples, materials made for the high surface energy layer 140 may be W, niobium (Nb), tantalum (Ta), their alloys, or any material with a surface energy greater than that of the back electrode layer 130. The high surface energy layer 140 may be formed on the back electrode layer 130 by sputtering or any other methods. The thickness of the layer 140 may be in the range of about 5 to 500 nm. In some implementations, the back electrode layer 130 may be replaced by the high surface energy layer 140. Alternatively, instead of having a high surface energy layer 140 as replacement of or on top of the back electrode layer 130, the substrate may be a high surface energy substrate. In particular, a high surface energy material may be sputtered onto the substrate before forming a light absorption layer on top of it. Alternatively, the back electrode layer 130 may be modified, such as through modification of processing parameters (e.g., sputtering pressure), in a way to expose higher energy lattice planes to increase interfacial bonding with the light absorption layer 150.

Formation of the light-absorption layer 150 may involve multiple steps. The first step is deposition of a thick layer of the precursor material, such as Cu and Ga, containing solution on the back electrode 130. The thickness of the precursor layer may be in a range from about 0.5 microns to about 2.5 micron. The precursor material may be dispersed in a solvent such as water, alcohol or ethylene glycol with the aid of organic surfactants and/or dispersing agents described herein to form an ink. The precursor layer is annealed with a ramp-rate of 1-5° C./sec, preferably over 5° C./sec, to a temperature of about 225° to about 575° C. preferably for about 30 seconds to about 600 seconds to enhance densification and/or alloying between Cu, In, and Ga in an atmosphere containing hydrogen or nitrogen gas, where the plateau temperature not necessarily is kept constant in time. Some embodiments may heat to a temperature of at least 500° C. Optionally, some embodiments may heat to a temperature of at least 505° C. Optionally, some embodiments may heat to a temperature of at least 510° C. Optionally, some embodiments may heat to a temperature of at least 515° C. Optionally, some embodiments may heat to a temperature of at least 520° C. Optionally, some embodiments may heat to a temperature of at least 525° C. Optionally, some embodiments may heat to a temperature of at least 530° C. Optionally, some embodiments may heat to a temperature of at least 535° C. Optionally, some embodiments may heat to a temperature of at least 540° C. Optionally, some embodiments may heat to a temperature of at least 545° C. Optionally, some embodiments may heat to a temperature of at least 550° C.

Subsequently, this annealed layer may be selenized with a ramp-rate of 1-5° C./sec, preferably over 5° C./sec, to a temperature of about 225 to 600° C. for a time period of about 60 seconds to about 10 minutes in Se vapor in a non-vacuum, where the plateau temperature not necessarily is kept constant in time, to form the thin-film light absorption layer 150 containing one or more chalcogenide compounds containing Cu, In, Ga, and Se. Some embodiments may heat to a temperature of at least 500° C. Optionally, some embodiments may heat to a temperature of at least 505° C. Optionally, some embodiments may heat to a temperature of at least 510° C. Optionally, some embodiments may heat to a temperature of at least 515° C. Optionally, some embodiments may heat to a temperature of at least 520° C. Optionally, some embodiments may heat to a temperature of at least 525° C. Optionally, some embodiments may heat to a temperature of at least 530° C. Optionally, some embodiments may heat to a temperature of at least 535° C. Optionally, some embodiments may heat to a temperature of at least 540° C. Optionally, some embodiments may heat to a temperature of at least 545° C. Optionally, some embodiments may heat to a temperature of at least 550° C.

Optionally, instead of this two-step approach, the layer of precursor material may be selenized without the separate annealing step in an atmosphere containing hydrogen or nitrogen gas, but may be densified and selenized in one step with a ramp-rate of 1-5° C./sec, preferably over 5° C./sec, to a temperature of 225 to 600° C. for a time period of about 120 seconds to about 20 minutes in an atmosphere containing either H2Se or a mixture of H2 and Se vapor. Some embodiment use only Se material and completely avoid H2Se. It should be understood that other embodiments may be configured to include S vapor or H2S to create the desired CIGS or CIGSS absorber. Details of formation of a I-III-VI₂ semiconductor film from particles of precursor materials are described in U.S. patent application Ser. No. 13/533,761 filed Jun. 26, 2012 and fully incorporated herein by reference.

With a high surface energy material underneath the light absorption layer 150, it would increase energy required to form voids. Thus, less voids may be formed during the formation of the light absorption layer on the high surface energy layer 140.

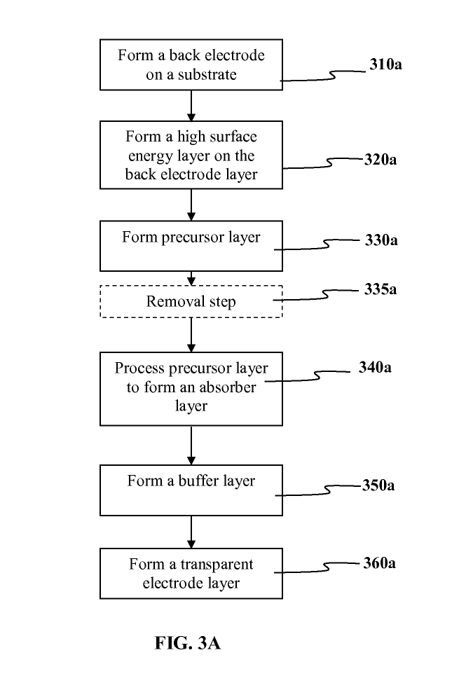

FIG. 2 schematically depicts an implementation of a roll-to-roll manufacturing process of a CIGS thin film. Implementations using I-III-VI₂ materials are well suited for use with roll-to-roll manufacturing and are equally well suited for a batch process. Specifically, as shown in FIG. 2, in a roll-to-roll manufacturing system 200 a flexible substrate 210, e.g., aluminum foil travels from a supply roll 202 to a take-up roll 204. In between the supply and take-up rolls, the substrate 210 passes a high surface energy layer formation apparatus 212, which deposits or otherwise forms the high surface energy layer on the substrate. The nature of the formation apparatus 212 depends on the process used to deposit or otherwise form the high surface energy layer. By way of example, and not by way of limitation, the deposition apparatus may be a sputter deposition chamber. Some possible alternatives to sputtering include, but are not limited to, printing, plating (e.g., electroplating) and evaporation.

In some implementations, the substrate may undergo one or more preliminary processing stages before passing the formation apparatus 212. For example, in the case of an aluminum foil substrate 210 a layer of molybdenum may be coated on the substrate surface before forming the high surface energy layer. In some implementations, it may be possible to use the high surface energy formation apparatus 212 to also form the molybdenum layer.

After the deposition apparatus 212, the substrate 210 may pass through a number of applicators 220A, 220B, 220C, e.g., gravure rollers and heater units 230A, 230B, 230C. It should be understood that these heater units may be thermal heaters or be laser annealing type heaters as described herein. Each applicator deposits a different layer or sub-layer of a precursor layer, e.g., as described above. The heater units are used to anneal the different layers and/or sub-layers to form dense films. In the example depicted in FIG. 2, applicators 220A and 220B may apply different sub-layers of a precursor layer. Heater units 230A and 230B may anneal each sub-layer before the next sub-layer is deposited. Alternatively, both sub-layers may be annealed at the same time. Applicator 220C may optionally apply an extra layer of material containing chalcogen or alloy or elemental particles. Heater unit 230C heats the optional layer and precursor layer as described above. Note that it is also possible to deposit the precursor layer (or sub-layers) then deposit any additional layer and then heat all three layers together to form a I-III-VI₂ compound film used for the photovoltaic absorber layer. The roll-to-roll system may be a continuous roll-to-roll and/or segmented roll-to-roll, and/or batch mode processing.

Referring back to FIG. 1, the buffer layer 160 is an n-type semiconductor thin film which serves as a junction partner between the compound film and the transparent conducting layer 170. By way of example, buffer layer 160 may include inorganic materials such as cadmium sulfide (CdS), zinc sulfide (ZnS), zinc hydroxide, zinc selenide (ZnSe), n-type organic materials, or some combination of two or more of these or similar materials, or organic materials such as n-type polymers and/or small molecules. Layers of these materials may be deposited, e.g., by chemical bath deposition (CBD) and/or chemical surface deposition (and/or related methods), to a thickness ranging from about 2 nm to about 1000 nm, more preferably from about 5 nm to about 500 nm, and most preferably from about 10 nm to about 300 nm. This may also be configured for use in a continuous roll-to-roll and/or segmented roll-to-roll and/or a batch mode system.

The transparent electrode layer 170 may include a transparent conductive layer 172 and a layer of metal (e.g., Al, Ag, Cu, or Ni) fingers 174 to reduce sheet resistance. The transparent conductive layer 172 may be inorganic, e.g., a transparent conductive oxide (TCO) such as but not limited to indium tin oxide (ITO), fluorinated indium tin oxide, zinc oxide (ZnO) or aluminum doped zinc oxide, or a related material, which can be deposited using any of a variety of means including but not limited to sputtering, evaporation, chemical bath deposition (CBD), electroplating, sol-gel based coating, spray coating, chemical vapor deposition (CVD), physical vapor deposition (PVD), atomic layer deposition (ALD), and the like. Alternatively, the transparent conductive layer 172 may include a transparent conductive polymeric layer, e.g. a transparent layer of doped PEDOT (Poly-3,4-Ethylenedioxythiophene), carbon nanotubes or related structures, or other transparent organic materials, either singly or in combination, which can be deposited using spin, dip, or spray coating, and the like or using any of various vapor deposition techniques. Optionally, it should be understood that intrinsic (non-conductive) i-ZnO or other intrinsic transparent oxide may be used between CdS and Al-doped ZnO. Combinations of inorganic and organic materials can also be used to form a hybrid transparent conductive layer. Thus, the layer 172 may optionally be an organic (polymeric or a mixed polymeric-molecular) or a hybrid (organic-inorganic) material. Examples of such a transparent conductive layer are described e.g., in commonly-assigned US Patent Application Publication Number 20040187317, which is incorporated herein by reference.

Those of skill in the art will be able to devise variations on the above embodiments that are within the scope of these teachings. For example, it is noted that in embodiments of the present invention, portions of the IB-IIIA precursor layers (or certain sub-layers of the precursor layers or other layers in the stack) may be deposited using techniques other than particle-based inks. For example precursor layers or constituent sub-layers may be deposited using any of a variety of alternative deposition techniques including but not limited to solution-deposition of spherical nanopowder-based inks, vapor deposition techniques such as ALD, evaporation, sputtering, CVD, PVD, electroplating and the like.

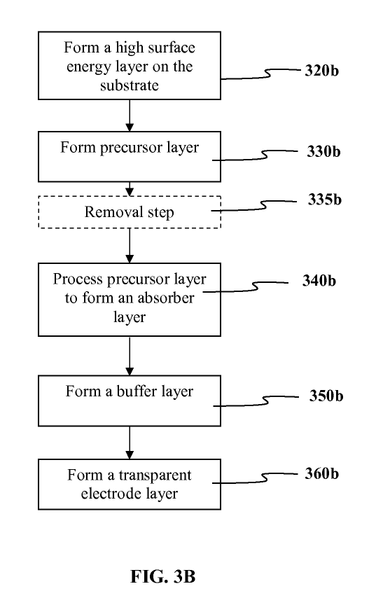

Referring now to FIG. 3A and 3B, flowcharts showing examples of methods in accordance with aspects of the present disclosure will now be described. FIG. 3A shows that at step 310a, a back electrode layer is first deposited by DC sputtering on a substrate. Step 320a may involve a step of forming a high surface energy layer on the back electrode layer. Optionally, step 310a may be omitted and the high surface energy layer may be formed directly on the substrate as shown in step 320b in FIG. 3B. At step 330a (330b), a precursor layer may be coated with the ink on top of the high surface energy layer. Optionally, there may be a step 335a (335b) of removing dispersant and/or other residual of the as-coated layer by methods such as but not limited to heating, washing, or the like. Optionally, step 335a (335b) may involve a step of removing solve after ink deposition by using a drying device such as but not limited to a drying tunnel/furnace. Step 340a (340b) shows the precursor layer is processed to form an absorber layer. In step 350a (350b) shows that a buffer layer may be formed over and/or in contact with the absorber layer. Step 360a (360b) shows that a transparent electrode may be formed over the n-type junction layer to create a stack that can function as a solar cell.

Without being tied to any theory of operation, it is expected that use of a high surface energy layer in accordance with aspects of the present disclosure can improve adhesion by reducing formation of voids at the interface between the electrode 130 and the absorber layer 150. The creation of a void requires the formation of two free surfaces. There is a free energy penalty for making free surfaces due to the presence of dangling bonds. The higher the surface energy of the electrode layer, the larger the energy penalty associated with creating the free surfaces. Therefore, the void fraction would decrease with increasing surface energy since increasing surface energy would make it energetically less favorable to form a void.

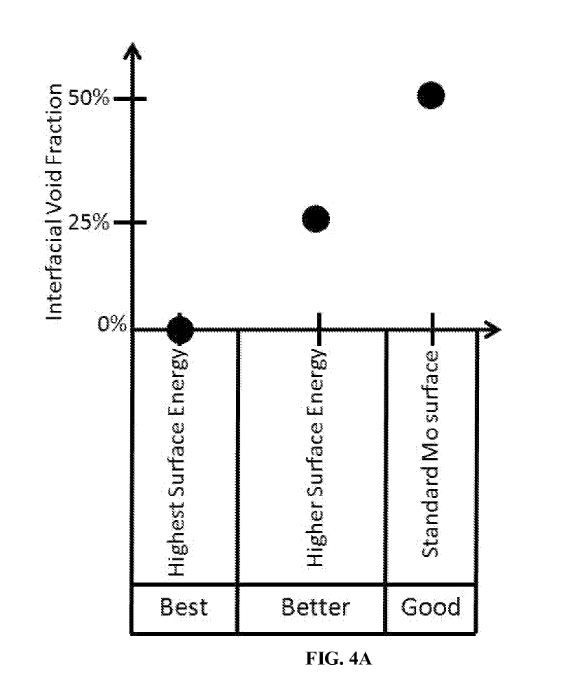

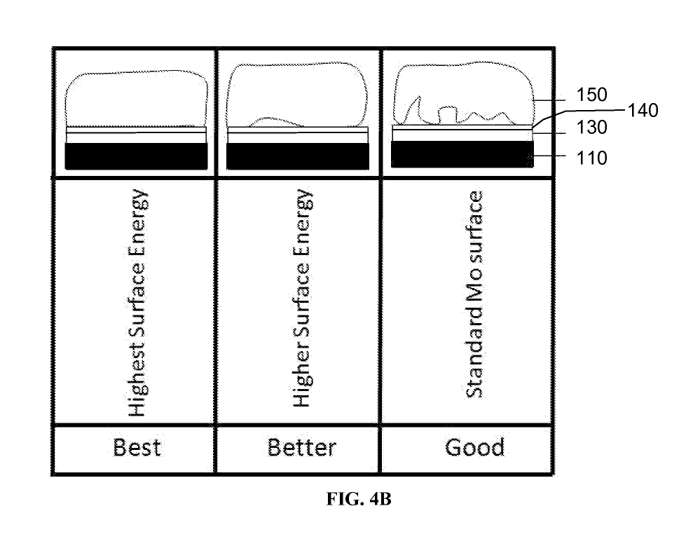

Advantages of the high surface energy layer in improving adhesion can be understood by referring to FIGS. 4A-4B. As seen in the graph depicted in FIG. 4A as the surface energy of the high surface energy layer 140 increases, the fraction of voids at the interface between the electrode layer 130 and the absorber 150 layer may be reasonably expected to decrease. As used herein, the term void fraction refers to an area fraction of an interface between the back contact and absorber layer that is occupied by voids. A void may be defined as the absence of a chemical bond between the absorber and back contact.

A void fraction between about 25% and about 50% may be considered to exhibit sufficiently good adhesion. A void fraction between about 10% and about 25% or less can be considered better. A void fraction of about 0% to about 10% may be considered best. The different void fractions corresponding to good, better and best adhesion may be visualized by referring to FIG. 4B which illustrates the void fractions in cross-sectional schematics.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.

What is claimed is:

1. A method of fabricating a solar cell, comprising:
forming at least one electrically conductive electrode layer above an aluminum foil substrate, and at least one electrically conductive diffusion barrier layer disposed between the aluminum foil substrate and the conductive electrode layer,
forming a high surface energy layer on the electrically conductive electrode layer, wherein the high surface energy layer is made of a material with a surface energy greater than a surface energy of the electrically conductive electrode layer; and
forming a light absorption layer on the high surface energy layer.

2. The method of claim 1, wherein the light absorption layer comprises Group I-III-VI₂ semiconductor materials.

3. The method of claim 1, further comprising forming a buffer layer on the light absorption layer to serve as a junction partner between the light absorption layer and a transparent electrode layer disposed on top of the buffer layer.

4. The method of claim 1, wherein the high surface energy layer increases energy required to form voids, thereby reducing voids formed during formation of the light absorption layer on the high surface energy layer.

5. The method of claim 1, further comprising forming a buffer layer on the light absorption layer.

6. The method of claim 5, further comprising forming a transparent electrode layer on the buffer layer, wherein the buffer layer serves as a junction partner between the light absorption layer and the transparent electrode layer.

7. A device, comprising:
an aluminum foil substrate;
at least one electrically conductive electrode layer above the aluminum foil substrate
at least one electrically conductive diffusion barrier layer disposed between the aluminum foil substrate and the conductive electrode layer,
a high surface energy layer on the electrically conductive electrode layer, wherein the high surface energy layer is made of a material with a surface energy greater than a surface energy of the electrically conductive electrode layer; and
a light absorption layer on the high surface energy layer.

8. The device of claim 7, wherein the high surface energy layer increases energy required to form voids, thereby reducing voids formed during formation of the light absorption layer on the high surface energy layer.

9. The device of claim 7, wherein the light absorption layer comprises Group I-III-VI₂ semiconductor materials.

10. The device of claim 7, further comprising a buffer layer on the light absorption layer.

11. The device of claim 10, further comprising a transparent electrode layer on the buffer layer, wherein the buffer layer serves as a junction partner between the light absorption layer and the transparent electrode layer.

12. The device of claim 7, wherein an interface between the electrode layer and the absorber layer is characterized by a void fraction of between about 25% and about 50%.

13. The device of claim 7, wherein an interface between the electrode layer and the absorber layer is characterized by a void fraction between about 10% and about 25%.

14. The device of claim 7, wherein an interface between the electrode layer and the absorber layer is characterized by a void fraction between 0% and about 10%.
